(19) United States
(12) Patent Application Publication
(10) Pub. No.: US 2009/0026477 A1
(43) Pub. Date: Jan. 29, 2009

(54) NOVEL PHOSPHOR AND FABRICATION OF THE SAME

(75) Inventors: Teng-Ming CHEN, Hsinchu City (TW); Yi-Chen Chiu, Hsinchu City (TW); Chien Hao Huang, Dongshih Township (TW)

Correspondence Address: STEIN, MCEWEN & BUI, LLP, 1400 EYE STREET, NW, SUITE 300, WASHINGTON, DC, 20005, US

(73) Assignee: National Chiao Tung University of Taiwan,

(21) Appl. No.: 12/172,483

(22) Filed: Jul. 14, 2008

(30) Foreign Application Priority Data
Jul. 25, 2007 (TW) 096127011
Jun. 2, 2008 (TW) 097120421

(51) Int. Cl. H01L 33/00; C01F 17/00

(52) U.S. Cl. 257/98; 423/263; 257/E33.061

(57) ABSTRACT

The present invention provides a novel phosphor represent by the following general formula:

Aₘ(B₁₋ₓCeₓ)ₙGe_{y}O_{z}
wherein A is at least one element selected from Mg and Zn; B is at least one element selected from the group consisting of La, Y and Gd; each of m, n, y and z is the number larger than 0 provided that 2m+3n+4y=2z; and x is in the range 0.0001≦x≦0.8.

### CROSS-REFERENCE TO RELATED APPLICATIONS

This application claims all benefits accruing under 35 U.S.C. §119 from Taiwanese Patent Application No. 096127011, filed on Jul. 25, 2007 and Taiwanese Patent Application No. 097120421, filed on Jun. 2, 2008 in the Intellectual Property Office Ministry of Economic Affairs, Republic of China, the disclosures of which are incorporated by reference herein.

### FIELD OF THE INVENTION

The present invention provides a series of novel phosphor composition, particularly for use in light-emitting devices, and fabrication thereof.

### DESCRIPTION OF THE RELATED PRIOR ART

The use of light-emitting diode (LED) to generating white light similar to sunlight thus generally replaces traditional white light lighting source, such as sunlight lamps, has been a main object of lighting source technical field in this century. As a comparison to traditional lighting sources, LED has advantages such as compactness, high brightness, usage life 10 times longer than traditional lighting equipments, lower cost in fabrication process and disposal treatment, and environmental friendliness. Therefore, LED has already been considered as the lighting source of next generation.

At present, the fabrication of white light LED can be divided as single-chip type and multi-chip type, wherein the multi-chip type using three kinds of LED with red, green and blue light, respectively, to generate white light. The advantage of multi-chip type LED is adjustable light color depending on different requirements. But, since it requires plural LEDs at same time, therefore, it has higher cost. Also, since materials of three kinds of LED are different, they have different drive voltages, and therefore, must design three types of circuits to control electric current. Besides, the decay rate, temperature characteristic and usage life of three types of LEDs are all different, thus it will lead to the variation of color of generated white light with time. Therefore, the product of commercial available white light LED and the trend in future will still take single-chip type as mainstream. As the fabrication method of single-chip type LED generally have three kinds as following:

(1) Combination of blue light LED with yellow light phosphor, which is using blue light LED to excite phosphor that can emit yellow light. The phosphor used is primarily a YAG phosphor with yttrium aluminum garnet structure ((Y,Gd)₃(Al,Ga)₅O₁₂:Ce (YAG:Ce), Y. Shimizu et al. U.S. Pat. No. 5,998,925) which emits yellow light that can mix up with un-absorbed blue light to generate white light. Most of white light LED currently commercially available are fabricated in this manner. The advantages of this type of LED are can emit white light with single chip, low cost and easy to fabricate, but it has drawbacks such as low light-emitting efficiency, poor color rendering, light color varies with different output currents, and un-uniform light color, etc.

(2) Combination of blue light LED with red light and green light phosphor, which is using blue light LED to separately excite phosphors can emit red light and those can emit green light. The phosphor composition used is primarily a sulfur-containing phosphor, which emits red light and green light thus can mix up with un-absorbed blue light to generate white light. The advantages of such LED is having a spectrum with three wavelength distribution and thus have a higher color rendering, and adjustable light color and color temperature.

(3) Combination of UV-LED with red, green and blue light phosphors, which is using UV light emitted by UV-LED to excite three or more kinds of phosphors that can emit red, blue and green light individually, and mix up the three color light emitted to generate white light. The white light generated in this manner is similar to sunlight lamp, it has advantages such as high color rendering, adjustable light color and color temperature, using high-converting efficiency phosphors can improve its light-emitting efficiency, and uniform light color without variation with current changes, but it also has drawbacks such as hard to mix its powder, hard to find phosphor with high efficiency and novel chemical composition.

Wherein the phosphor, or so called fluorescence converting material (or fluorescence converting compound), can converts UV light or blue light into visible light with different wavelengths, and the color of produced light depends on the specific composition of phosphor. The phosphor may have only one phosphor composition or have two or more phosphor compositions. However, if we like to take LED as lighting source, only LED with brighter and whiter light can used in LED lamps. Therefore, the phosphor is generally coated on LED to produce white light. Each kind of phosphor under excitation of different wavelength can be converted into lights with different colors, for example, under excitation of near UV or blue light LED with wavelength of 365 nm-500 nm, phosphors can be converted into visible light. And the visible lights produced by the conversion of excited phosphor have characteristics of high luminescence intensity and high brightness.

Two colors visually feeling the same may actually composed of lights with wavelength different from each other. Based on the three primary colors, i.e., red, blue and green, visually various colors are achieved by combining the primaries at various ratios, i.e. so called principle of the three primary colors. Commission Internationale de l'Eclairage (CIE) has determined the equivalent unit for primary colors, and the luminous flux of standard white light is defined as:

r:g:b=1:4.5907:0.0601.

As equivalent unit for primary colors is determined, color combination relationship for white light Fw is:

Fw=1[R]+1[G]+[B]

wherein R represents red light, G represents green light, and B represents blue light.

To light F with any color, color combination equation thereof is Fw=r[R]+g[G]+b[B], wherein r, g and b represents coefficients of red, blue and green, respectively, determined experimentally. Corresponding luminous flux is Fw=680(R+4.5907G+0.0601B) lumens (Im, illumination unit), wherein the ratio among r, g and b determines chromaticity (degree of color saturation), and the values determine the brightness of combined color. Relationship of three primary colors r[R], g[G] and b[B] can be expressed by matrix after normalization:

F=X[X]+Y[Y]+Z[Z]=m{x[X]+y[Y]+z[Z]},

wherein m=X+Y+Z, and x=(X/m), y=(Y/m) and z=(Z/m). Every light-emitting wavelength corresponds to specific r, g and b values. By defining sum of r values in VIS region as X, sum of g values as Y, and sum of b values as Z, then chromaticity of light emitted from phosphor powder can be expressed by x, y coordinates system, which is named C.I.E. 1931 Standard Colorimetric System (C.I.E. Chromaticity Coordinates). As a spectrum is measured, contribution from lights of each wavelength are calculated, then exact position on chromaticity coordinates is pointed, and color of light emitted from phosphor powder is thus defined.

However, in the application of using blue light LED and yellow light phosphor to fabricate white light LED, the currently available yellow light phosphors are lack of contribution in red spectrum in color rendering and have drawbacks such as un-uniform light color and low light-emitting efficiency. In this connection, if a phosphor with improved color rendering index, high stability and lower cost can be provided and applied in the phosphor layer of white light LED, the color temperature of white light LED can be adjusted and color rendering of LED can be improved and, eventually, it can used to replace commercially available fluorescence converting materials for LED fabrication nowadays.

### SUMMARY OF THE INVENTION

The present invention disclosed a yellow light phosphor with low fabrication cost, stable material and novel chemical compositions, which can be excited by blue light emitting LED or laser diode to emit yellow light and to mix with un-absorbed blue light to generate white light. The present invention also provides white light light-emitting device with high color rendering.

The present invention provides a series of phosphor with novel chemical composition, which is a Ce³⁺-doped germinate material which is completely different from that of YAG:Ce or silicate-based phosphors, expressed by the following general formula:

Aₘ(B₁₋ₓCeₓ)ₙGe_{y}O_{z}

wherein A is at least one element select from Mg and Zn; B is at least one element select from the group consist of La, Y, Gd; each of m, n, y, z is the number larger than 0, providing that 2m+3n+4y=2z; x is in the range of 0<x<1, preferably 0.005≦x≦0.01, more preferably 0.01≦x≦0.10, most preferable 0.03≦x≦0.05. More specifically, said phosphor material can be expressed by the general formula Mg₃(Y₁₋ₓCeₓ)₂Ge₃O₁₂, wherein x is in the range of 0.0001≦x≦0.8, preferably 0.01≦x≦0.05, more preferably x=0.03.

The phosphor can be excited by a primary radiation emitted by a light-emitting element thus emitting a secondary radiation, wherein the wavelength of the primary radiation emitted by the light-emitting element is in the range 450 nm˜500 nm, and the wavelength of the secondary radiation emitted by the excited phosphor is longer than the wavelength of the primary radiation emitted by the light-emitting element.

Specifically, the wavelength of the primary radiation emitted by said light-emitting element is preferably in the range 460 nm˜480 nm, thus the wavelength of the secondary radiation emitted by the excited phosphor is in the range 500 nm˜700 nm, with the CIE Chromaticity Coordinates (x,y) is in the range 0.40≦x≦0.60, 0.40≦y≦0.60, which is yellow in color.

Further, the wavelength of the primary radiation emitted by said light-emitting element is more preferably in the range 460 nm˜470 nm, thus the wavelength of the secondary radiation emitted by the excited phosphor is in the range 550 nm˜570 nm, with CIE Chromaticity Coordinates (x,y) is in the range 0.45≦x≦0.55, 0.45≦y≦0.55, which is yellow in color.

The present invention also provides a fabrication method of the above phosphor, comprising: stoichiometrically weighed materials (A) at least one oxide select from the group consisting of MgO and ZnO, (B) at least one oxide select from the group consisting of Y₂O₃, La₂O₃ and Gd₂O₃, (C) CeO₂, and (D) GeO₂; grounding the weighed material and mixing them well; transferring the obtained mixture into an alumina boat crucible, and carrying out the solid-state synthesis at 1200˜1400° C. with a reaction time of 4˜10 hours.

Furthermore, the present invention provides a light-emitting device, comprising a light-emitting element and a phosphor, wherein the light-emitting element emits a primary radiation with wavelength in the range 450 nm˜480 nm, and the phosphor can be excited by absorbing part of primary radiation emitted by the light-emitting element and thus emitting a secondary radiation with wavelength different from that of the primary radiation, and the phosphor can select from the above mentioned phosphor.

The light-emitting element can be a semiconductor light-emitting source, a light-emitting diode or an organic light-emitting device, and the phosphor is coated on the top or surface of the light-emitting element. The wavelength of the secondary radiation emitted by the excited phosphor is longer than that of the primary radiation emitted by the light-emitting element. Further, the light-emitting device is formed by packaging the phosphor on the top or surface of the light-emitting element, after the phosphor is excited by the primary radiation emitted by the light-emitting element, the secondary radiation emitted by the excited phosphor can combined with the un-absorbed primary radiation to generate a white light.

### BRIEF DESCRIPTION OF THE DRAWINGS

FIG. 1 shows the X-ray diffractograms of Example 1.

FIG. 2 shows the X-ray diffractograms of the samples synthesized at various synthetic temperatures obtained in a preferred embodiment.

FIG. 3 shows the fluorescence emission and excitation spectra for the said phosphors with different Ce³⁺ doping concentrations in Example 1.

FIG. 4 shows the relationship between the luminous intensity and luminance for the said phosphors with different Ce³⁺ doping concentrations in a preferred embodiment.

FIG. 5 shows the reflection spectrum obtained in a preferred embodiment.

FIG. 6 shows the comparison of the fluorescence emission and excitation spectra between the preferred embodiment and commercial product.

FIG. 7 shows the CIE chromaticity coordinates obtained in a preferred embodiment.

FIG. 8 shows X-ray diffractograms of Example 2.

FIG. 9 shows the fluorescence emission and excitation spectra for the said phosphors with different Ce³⁺ doping concentrations in Example 2.

FIG. 10 shows the relationship between the luminous intensity and the doping concentration of Ce³⁺ in Example 2.

FIG. 11 shows X-ray diffractograms of Example 3.

FIG. 12 shows the fluorescence emission and excitation spectra for the said phosphors with different Ce³⁺ doping concentrations in Example 3.

FIG. 13 shows X-ray diffractograms of Example 4.

FIG. 14 shows the fluorescence emission and excitation spectra for the said phosphors with different Zn²⁺ doping concentrations in Example 4.

FIG. 15 shows the relationship between the luminance and the doping concentration of Zn²⁺ in Example 1˜3.

FIG. 16 shows the relationship between the luminous intensity and the doping concentration of Ce³⁺ in Example 1˜3.

FIG. 17 shows the relationship between the luminance and the doping concentration of Ce³⁺ in Example 1˜3.

### DETAILED DESCRIPTION OF THE INVENTION

The present invention describes in detail by referring to embodiments and drawings, in order to facilitate a better understanding of the present components and characteristics thereof for those skilled in this field, hence the objects, technical contents, features, and effectiveness of the present invention are more easily to be known.

### Example 1

### Mg₃(Y₁₋ₓCeₓ)₂Ge₃O₁₂

According to the chemical composition of Mg₃(Y₁₋ₓCeₓ)₂Ge₃O₁₂, stoichiometric amount of MgO, Y₂O₃, GeO₂ and CeO₂ are weighed, wherein x is 0.005, 0.01, 0.03, 0.05 and 0.1. The weighed materials were ground thoroughly and mixed well, the obtained mixture was transferred into alumina boat crucible and loaded into a high temperature furnace to carry out solid-state sintering at 1200˜1400° C. with a reaction time of 4˜10 hours.

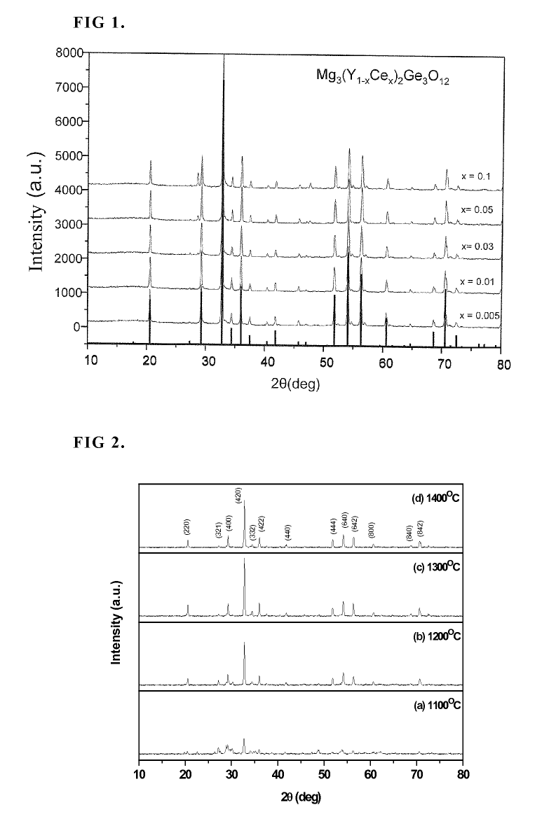

The results obtained by using X-ray diffractometer (Bruker AXS D8 advance type) to confirm the purity of crystalline phase and structural analysis are shown in FIG. 1. From the X-ray diffractograms, we have observed that no impurity was found, also proving that the phosphor synthesized by present invention is a pure substance.

Also at various synthetic temperatures, the X-ray diffraction profile of a preferred phosphor Mg₃(Y_{0.97}Ce_{0.03})₂Ge₃O₁₂ of the present invention has been measured and the results are shown in FIG. 2. From the X-ray diffractogram it is seen that no impurity is present, also proving that the phosphor synthesized by present invention is a pure substance.

Since the light emitting wavelength of blue light LED is between 450 nm˜500 nm, therefore a xenon lamp with the same wavelength can be used as a simulated excitation source to test the luminous properties of phosphors of the present invention.

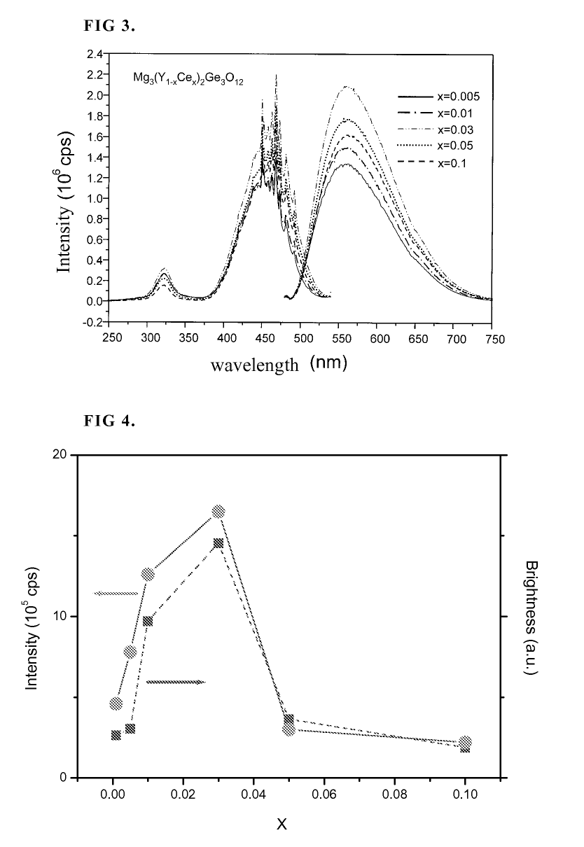

The fluorescence emission and excitation spectra of phosphor Mg₃(Y₁₋ₓCeₓ)₂Ge₃O₁₂ were measured by using the Spex Fluorolog-3 spectrofluorometer (Jobin-Yvon Spex S.A., USA) equipped with 450 W xenon lamp and the results are shown in FIG. 3. There is a broad band absorption in blue and near UV region, the wavelength of the emission band is centered at about 562 nm and the band width is about 250 nm. The emission band is attributed to the transitions 5d→²F_{5/2} and 5d→²F_{7/2} of Ce³⁺, proved that the phosphor of the present invention can be excited by blue light, and the un-absorbed blue light in combination with the yellow light emitted by the phosphor itself can combine to produce white light.

Using color analyzer (DT-100 Color Analyzer, manufactured by LAIKO Co. Ltd., Japan) in combination with the fluorescence spectrometer, we have measured the luminance and chromaticity of phosphor.

FIG. 4 shown the relationship between the luminous intensity and luminance of phosphor Mg₃(Y₁₋ₓCeₓ³⁺)₂Ge₃O₁₂ with various Ce³⁺ doping concentrations, the left arrow (circle solid line) represents luminous intensity and right arrow (square dashed line) represents the luminance. These results indicate that when the phosphor is doped with 3 mole % of Ce³⁺, it exhibits the highest luminous intensity and luminance.

A reflection spectrum was measured by using a U-3010 UV-Vis Spectrometer (Hitachi Co., Japan) with wavelength ranging from 190 nm to 1000 nm to investigate the absorption region of the preferred phosphor Mg₃(Y_{0.97}Ce_{0.03})₂Ge₃O₁₂ of the present invention and the host Mg₃Y₂Ge₃O₁₂ without Ce³⁺ ion doping and the results are summarized in FIG. 5. When Ce³⁺ ions are not doped in the host Mg₃Y₂Ge₃O₁₂, absorption only appeared in the region between 200 nm˜300 nm, but when the Ce³⁺ ions are doped, a broad absorption band in blue light region between 400 nm˜500 nm can be observed. Therefore, this observation indicates that the phosphor of the present invention can absorb blue light effectively.

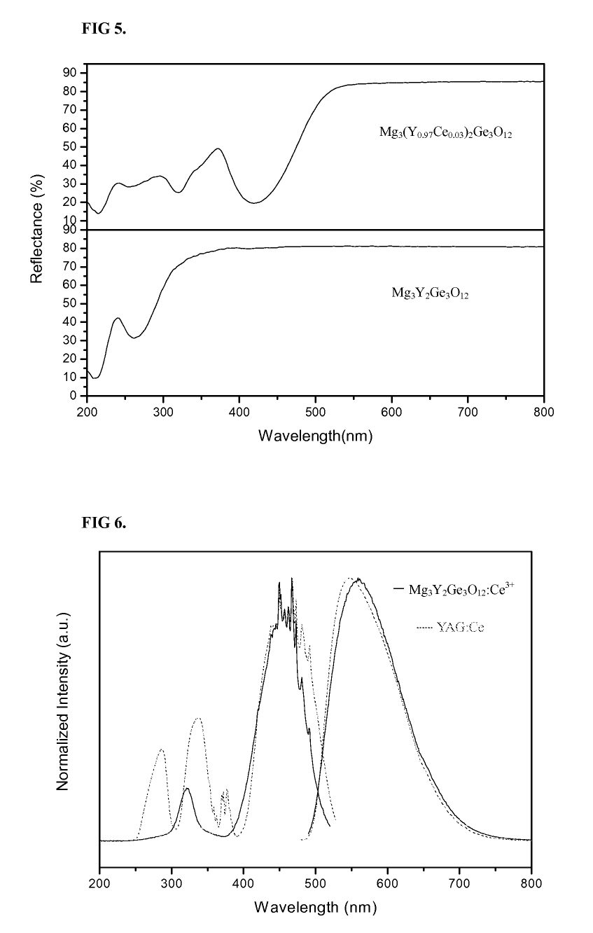

FIG. 6 shows the photoluminescence and excitation spectra of the preferred embodiment Mg₃(Y_{0.97}Ce_{0.03})₂Ge₃O₁₂ and commercially available YAG:Ce (Nichia Co., Japan). As a result of comparison, the phosphor of the present invention exhibits higher excitation efficiency than that of the YAG:Ce commodity.

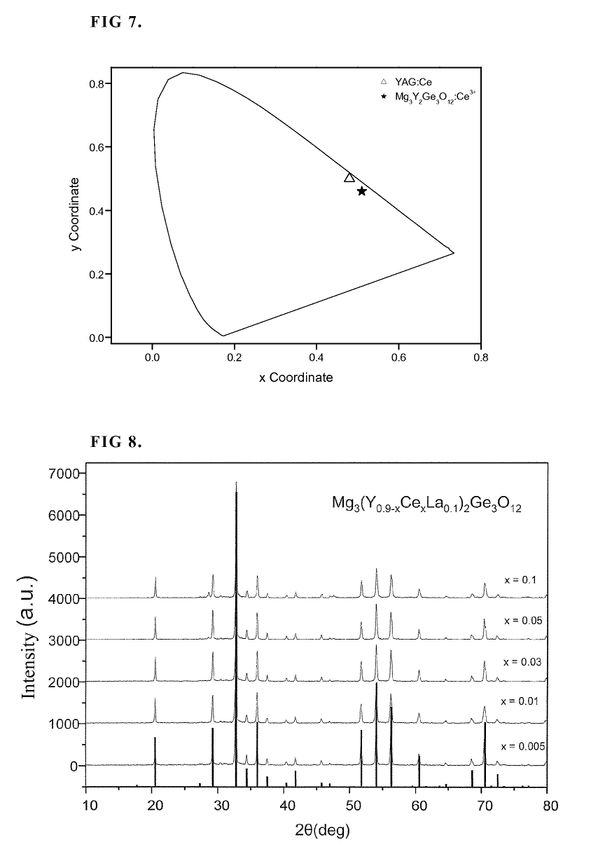

FIG. 7 shows the CIE chromaticity diagram of Mg₃(Y_{0.97}Ce_{0.03})₂Ge₃O₁₂ measured under the excitation of light with wavelength of 467 nm, the experimental chromaticity coordinate is (0.506,0.465). As compared to the YAG:Ce commodity, the phosphor of the present invention is much closer to yellow light, and the color saturation is higher.

According to the above methods, phosphors doped with different concentrations of Ce³⁺ are measured, the results are shown in Table 1.

### Example 2

### Mg₃(Y_{0.9-x}CeₓLa_{0.1})₂Ge₃O₁₂

Besides adding 10 mole % of La₂O₃, the processing conditions are similar as those described in example 1. The results of measurements are shown in Table 1.

FIG. 8 shows the X-ray diffractograms of Mg₃(Y_{0.9-x}CeₓLa_{0.1})₂Ge₃O₁₂ phosphor. From the X-ray diffractogram, we have observed that no impurity is present, also proving that the phosphor synthesized by present invention is a pure substance.

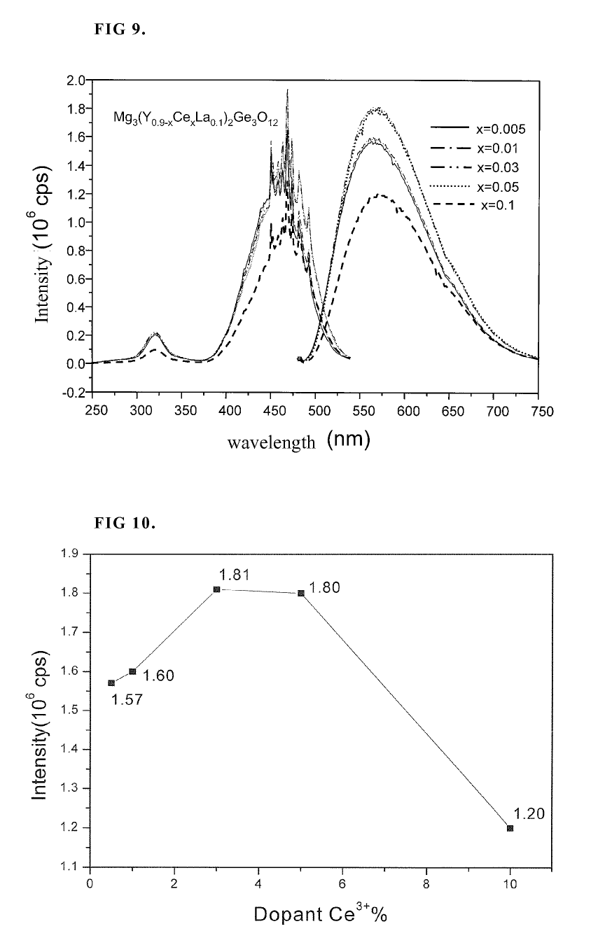

FIG. 9 shows emission and excitation spectra of Mg₃(Y_{0.9-x}CeₓLa_{0.1})₂Ge₃O₁₂ phosphors.

FIG. 10 shows the luminous intensity of phosphor Mg₃(Y_{0.9-x}CeₓLa_{0.1})₂Ge₃O₁₂ with various Ce³⁺ doping concentrations.

### Example 3

### Mg₃(Y_{0.9-x}CeₓGd_{0.1})₂Ge₃O₁₂

Besides adding 10 mole % of Gd₂O₃, the processing conditions are similar as those described in example 1. The results of measurements are shown in Table 1.

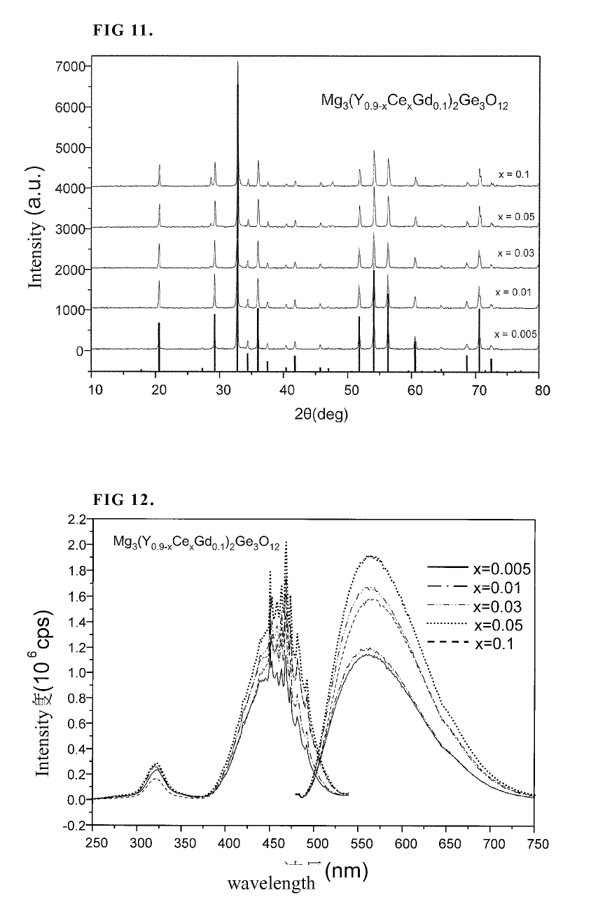

FIG. 11 shows the X-ray diffractograms of Mg₃(Y_{0.9-x}CeₓGd_{0.1})₂Ge₃O₁₂ phosphors. From the X-ray diffractogram, we have observed that no impurity is present, also proving that the phosphor synthesized by present invention is a pure substance.

FIG. 12 shows emission and excitation spectra of Mg₃(Y_{0.9-x}CeₓGd_{0.1})₂Ge₃O₁₂ phosphor.

### Example 4

### (Mg₁₋ₓZnₓ)₃(Y_{0.99}Ce_{0.01})Ge₃O₁₂

According to the chemical composition of (Mg₁₋ₓZnₓ)₃(Y_{0.99}Ce_{0.01})Ge₃O₁₂, stoichiometric amounts of MgO, ZnO, Y₂O₃, GeO₂ and CeO₂ are weighed, wherein x is 0.01, 0.03, and 0.05. Others are prepared according to the processing conditions described in example 1. The results are shown in Table 1.

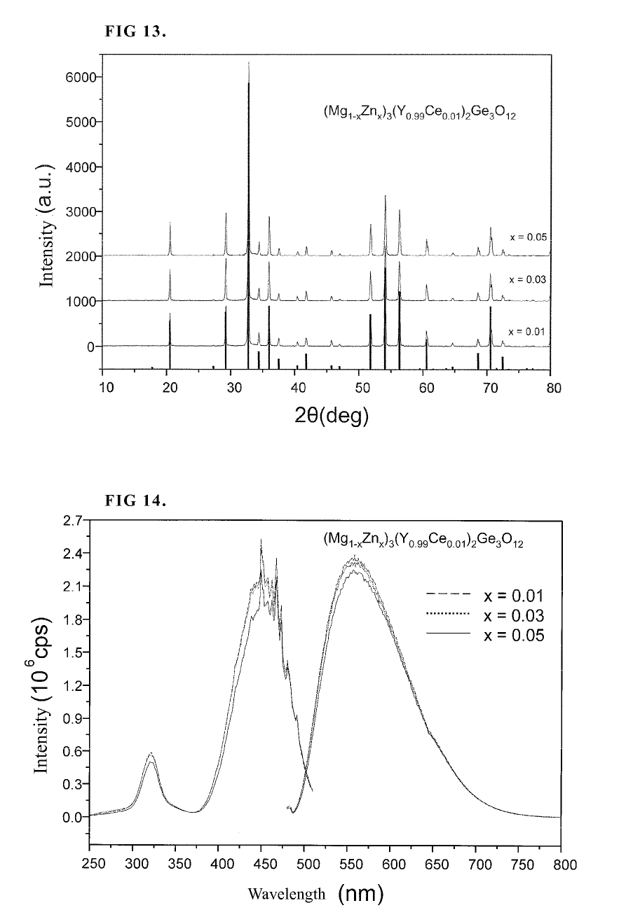

FIG. 13 shows the X-ray diffractogram of (Mg₁₋ₓZnₓ)₃(Y_{0.99}Ce_{0.01})Ge₃O₁₂ phosphors. From the X-ray diffractogram, no impurity is found, indicating that the phosphor synthesized by present invention is a pure substance.

FIG. 14 shows emission and excitation spectra of (Mg₁₋ₓZnₓ)₃(Y_{0.99}Ce_{0.01})Ge₃O₁₂ phosphors.

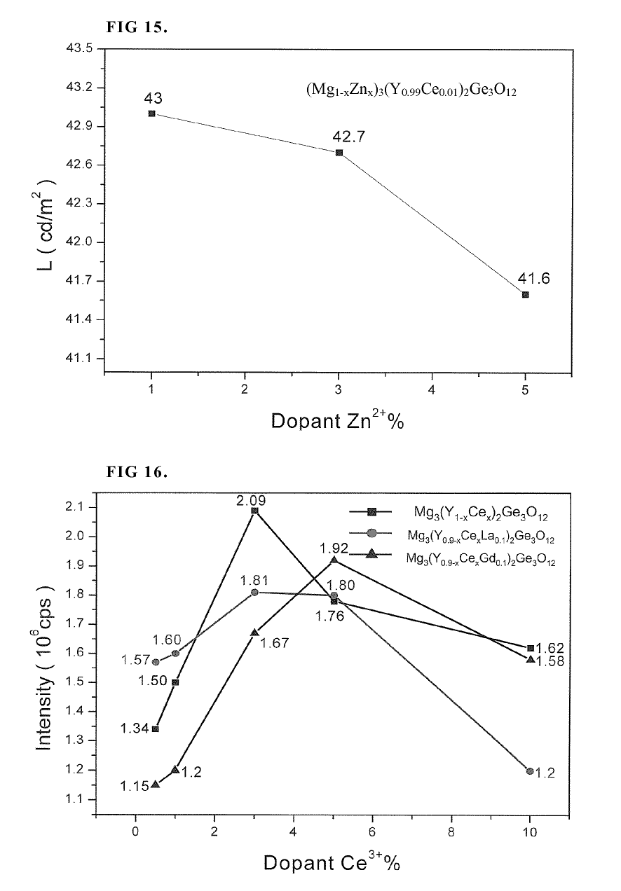

FIG. 15 shows the luminance of a phosphor (Mg₁₋ₓZnₓ)₃(Y_{0.99}Ce_{0.01})Ge₃O₁₂ with various Zn²⁺ doping concentration.

TABLE 1

| | | | Excitation | Emission | CIE | relative |
|---|---|---|---|---|---|---|
| Example | | | wavelength | wavelength | coordinates | luminance |
| No. | Phosphor | x | (nm) | (nm) | (x, y) | (cd/m2) |
| 1 | Mg₃(Y₁₋ₓCeₓ)₂Ge₃O₁₂ | 0.005 | 467 | 560 | (0.497, 0.465) | 26.9 |
| | | 0.01 | 467 | 561 | (0.498, 0.465) | 34.8 |
| | | 0.03 | 467 | 559 | (0.506, 0.465) | 43.9 |
| | | 0.05 | 467 | 560 | (0.508, 0.465) | 40.8 |
| | | 0.1 | 467 | 561 | (0.509, 0.465) | 34 |
| 2 | Mg₃(Y_{0.9-x}CeₓLa_{0.1})₂Ge₃O₁₂ | 0.005 | 467 | 564 | (0.513, 0.458) | 32.8 |
| | | 0.01 | 467 | 564 | (0.516, 0.458) | 35.5 |
| | | 0.03 | 467 | 565 | (0.521, 0.458) | 42 |
| | | 0.05 | 467 | 568 | (0.523, 0.458) | 39.3 |
| | | 0.1 | 467 | 569 | (0.530, 0.446) | 28.2 |
| 3 | Mg₃(Y_{0.9-x}CeₓGd_{0.1})₂Ge₃O₁₂ | 0.005 | 467 | 562 | (0.502, 0.458) | 25.9 |
| | | 0.01 | 467 | 563 | (0.502, 0.458) | 29.2 |
| | | 0.03 | 467 | 568 | (0.510, 0.463) | 34.9 |
| | | 0.05 | 467 | 568 | (0.514, 0.462) | 39.4 |
| | | 0.1 | 467 | 569 | (0.517, 0.458) | 33.2 |
| 4 | (Mg₁₋ₓZnₓ)₃(Y_{0.99}Ce_{0.01})Ge₃O₁₂ | 0.01 | 467 | 558 | (0.495, 0.468) | 43 |
| | | 0.03 | 467 | 555 | (0.495, 0.467) | 42.7 |
| | | 0.05 | 467 | 555 | (0.499, 0.465) | 41.6 |

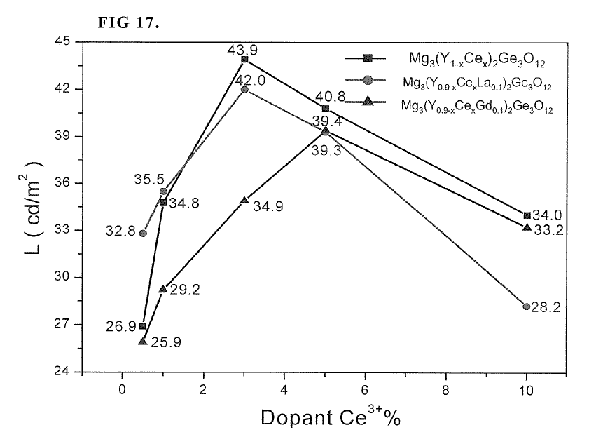

As shown by FIGS. 16 and 17, the Ce³⁺ doping novel phosphor of the present invention shows high luminous intensity and luminance. The Ce³⁺ ion doping concentration is preferably 0.5˜10% by mole, more preferably 1˜10% by mole, and most preferably 3˜5% by mole.

Further, the present phosphor can be used in LED, particularly white LED. In order to achieve better color effectiveness, it can be used alone or it can be used in combination with other red or blue light phosphors for other chromogenic purposes.

A preferred embodiment of the present invention provides light-emitting device, comprising a light-emitting element which can be a semiconductor light-emitting source, i.e., LED chip, and a conductive lead connected to the LED chip. The conductive lead is supported by sheet-like electrodes which supply current to the LED to enable radiation emitting. The light-emitting device can comprise any blue light semiconductor as lighting source, the radiation emitted by which directly irradiates on the phosphor composition of the present invention to generate white light.

In a preferred embodiment of the present invention, LED can be doped with various impurities. Said LED can comprise various suitable III-V, II-VI or IV-IV semiconductor layers, and the wavelength of the radiation emitted by which preferably is 250˜500 nm. Said LED comprises at least a semiconductor layer composed of GaN, ZnSe or SiC. For example, a LED composed of a nitride represented by the general formula InᵢGaⱼAlₖN (wherein 0≦i; 0≦j; 0≦k, and i+j+k=1) emits light with wavelength in the range 250 nm˜500 nm. Use of the above LED semiconductor has been known and is useful as excitation source in the present invention. However, the excitation lighting source for the present invention is not limited to the above LED, and any kind of semiconductor with light emitting capability, including semiconductor laser lighting source, are applicable.

Generally, the mentioned LEDs are directed to inorganic ones, however, those skilled in this field can easily understand that the mentioned LEDs are replaceable by organic ones or any other radiation sources. The present phosphor is coated on said LEDs used as excitation source to generate white light. Therefore, as can be seen from the above preferred embodiments, the present phosphor is capable of emitting yellow light with excellent luminance and color saturation, in comparison to those of commercial available YAG:Ce.

Additional advantages and modifications will readily occur to those skilled in the art. Therefore, the invention in its broader aspects is not limited to the specific details and illustrative example shown and described herein. Accordingly, various modifications may be made without departing from the spirit or scope of the general invention concept as defined by the appended claims and their equivalents.

1. A phosphor which is formed from Ce³⁺-doped germinate represented by a formula below:
Aₘ(B₁₋ₓCeₓ)ₙGe_{y}O_{z}
wherein:
A is at least one element selected from Mg and Zn;
B is at least one element selected from the group consisting of La, Y and Gd;
m, n, y, and z are numbers larger than 0 respectively, provided that 2m+3n+4y=2z; and x is in the range 0<x<1.

2. The phosphor according to claim 1, wherein x is in the range of 0.005≦x≦0.1.

3. The phosphor according to claim 2, wherein x is in the range of 0.01≦x≦0.1.

4. The phosphor according to claim 3, wherein x is in the range of 0.03≦x≦0.05.

5. The phosphor according to claim 1, wherein, when A is selected from Mg and B is selected from Y, the formula is represented as follows:
Mg₃(Y₁₋ₓCeₓ)₂Ge₃O₁₂,
wherein x is in the range of 0.0001≦x≦0.8.

6. The phosphor according to claim 5, wherein x is in the range of 0.005≦x≦0.1.

7. The phosphor according to claim 6, wherein x is 0.03.

8. The phosphor according to claim 1, wherein the phosphor emits a secondary radiation by the excitation of a primary radiation emitted by a light-emitting element.

9. The phosphor according to claim 8, wherein a wavelength of the primary radiation is in the range of 450 nm˜500 nm, and a wavelength of the secondary radiation is longer than that of the primary radiation.

10. The phosphor according to claims 9, wherein the wavelength of the primary radiation is in the range of 460 nm˜480 nm, and the wavelength of the secondary radiation is in the range of 500 nm˜700 nm with CIE chromaticity coordinate value (x,y) is in the range 0.40≦x≦0.60 and 0.40≦y≦0.60.

11. The phosphor according to claims 10, wherein the wavelength of the primary radiation is in the range of 460 nm˜470 nm, and the wavelength of the secondary radiation is in the range of 550 nm˜570 nm with CIE chromaticity coordinate value (x,y) is in the range 0.45≦x≦0.55 and 0.45≦y≦0.55.

12. A process for producing the phosphor according to claim 1 comprising:
stoichiometrically weighed materials (A) at least one oxide selected from MgO and ZnO, (B) at least one oxide selected from the group consisting of Y₂O₃, La₂O₃ and Gd₂O₃, (C) CeO₂ and (D) GeO₂;
grinding and mixing the weighed materials; and
transferring the mixture into an alumina boat crucible, and conducting a solid-state synthesis of the mixture at 1200˜1400° C.

13. The process according to claim 12, wherein the solid-state synthesis of the mixture requires a reaction period of 4˜10 hours.

14. A light-emitting device which comprises a light-emitting element and a phosphor, wherein:
the light-emitting element emits a primary radiation with a wavelength in the range of 450 nm˜480 nm,
the phosphor is a phosphor according to claim 1, and
the phosphor absorbs part of the primary radiation and then emits a secondary radiation with a wavelength different from that of the primary radiation.

15. The light-emitting device according to claim 14, wherein the wavelength of the secondary radiation is longer than that of the primary radiation.

16. The light-emitting device according to claim 14, wherein the light-emitting element represents a semiconductor light source, a light-emitting diode, a laser diode, or an organic light-emitting device.

17. The light-emitting device according to claim 14, wherein the phosphor is coated on a surface or top of the light-emitting device.

18. The light-emitting device according to claim 14, wherein the phosphor is packaged on a surface or top of the light-emitting device.
